(19) United States
(12) Patent Application Publication
(10) Pub. No.: US 2004/0133698 A1
(43) Pub. Date: Jul. 8, 2004

(54) Apparatus and method for op code extension in packet groups transmitted in trace streams

(76) Inventors: Gary L. Swoboda, Sugar Land, TX (US); Bryan Thome, Missouri City, TX (US)

Correspondence Address: TEXAS INSTRUMENTS INCORPORATED, P O BOX 655474, M/S 3999, DALLAS, TX, 75265

(21) Appl. No.: 10/729,191

(22) Filed: Dec. 5, 2003

Related U.S. Application Data
(60) Provisional application No. 60/434,125, filed on Dec. 17, 2002.

(51) Int. Cl. G06F 15/16; H03K 19/003

(52) U.S. Cl. 709/236; 714/45

(57) ABSTRACT

In a test and debug system, information is transmitted from the target processor to the host processor in groups of packets that can include one or more packets. The packets include an extension portion and a payload portion. Because the packets have relatively small number of logic signals, the extension portions can be used to determine, based on header information, the number of packet sub-group and the number of packets in each packet subgroup.

This application claims priority under 35 USC §119(e) (1) of Provisional Application No. 60/434,125 (TI-34762P) filed Dec. 17, 2002.

### RELATED APPLICATIONS

U.S. patent application (Attorney Docket No. TI-34654), entitled APPARATUS AND METHOD FOR SYNCHRONIZATION OF TRACE STREAMS FROM MULTIPLE PROCESSORS, invented by Gary L. Swoboda, filed on even date herewith, and assigned to the assignee of the present application; U.S. patent application (Attorney Docket No. TI-34655), entitled APPARATUS AND METHOD FOR SEPARATING DETECTION AND ASSERTION OF A TRIGGER EVENT, invented by Gary L. Swoboda, filed on even date herewith, and assigned to the assignee of the present application; U.S. patent application (Attorney Docket No. TI-34656), entitled APPARATUS AND METHOD FOR STATE SELECTABLE TRACE STREAM GENERATION, invented by Gary L. Swoboda, filed on even date herewith, and assigned to the assignee of the present application; U.S. patent application (Attorney Docket No. TI-34657), entitled APPARATUS AND METHOD FOR SELECTING PROGRAM HALTS IN AN UNPROTECTED PIPELINE AT NON-INTERRUPTIBLE POINTS IN CODE EXECUTION, invented by Gary L. Swoboda and Krishna Allam, filed on even date herewith, and assigned to the assignee of the present application; U.S. patent application (Attorney Docket No. TI-34658), entitled APPARATUS AND METHOD FOR REPORTING PROGRAM HALTS IN AN UNPROTECTED PIPELINE AT NON-INTERRUPTIBLE POINTS IN CODE EXECUTION, invented by Gary L. Swoboda, filed on even date herewith, and assigned to the assignee of the present application; U.S. patent application (Attorney Docket No. TI-34659), entitled APPARATUS AND METHOD FOR A FLUSH PROCEDURE IN AN INTERRUPTED TRACE STREAM, invented by Gary L. Swoboda, filed on even date herewith, and assigned to the assignee of the present application; U.S. patent application (Attorney Docket No. TI-34660), entitled APPARATUS AND METHOD FOR CAPTURING AN EVENT OR COMBINATION OF EVENTS RESULTING IN A TRIGGER SIGNAL IN A TARGET PROCESSOR, invented by Gary L. Swoboda, filed on even date herewith, and assigned to the assignee of the present application; U.S. patent application (Attorney Docket No. TI-34661), entitled APPARATUS AND METHOD FOR CAPTURING THE PROGRAM COUNTER ADDRESS ASSOCIATED WITH A TRIGGER SIGNAL IN A TARGET PROCESSOR, invented by Gary L. Swoboda, filed on even date herewith, and assigned to the assignee of the present application; U.S. patent application (Attorney Docket No. TI-34662), entitled APPARATUS AND METHOD DETECTING ADDRESS CHARACTERISTICS FOR USE WITH A TRIGGER GENERATION UNIT IN A TARGET PROCESSOR, invented by Gary Swoboda and Jason L. Peck, filed on even date herewith, and assigned to the assignee of the present application; U.S. patent application (Attorney Docket No. TI-34663), entitled APPARATUS AND METHOD FOR TRACE STREAM IDENTIFICATION OF A PROCESSOR RESET, invented by Gary L. Swoboda, Bryan Thome and Manisha Agarwala, filed on even date herewith, and assigned to the assignee of the present application; U.S. Pat. (Attorney Docket No. TI-34664), entitled APPARATUS AND METHOD FOR TRACE STREAM IDENTIFICATION OF A PROCESSOR DEBUG HALT SIGNAL, invented by Gary L. Swoboda, Bryan Thome, Lewis Nardini and Manisha Agarwala, filed on even date herewith, and assigned to the assignee of the present application; U.S. patent application (Attorney Docket No. TI-34665), entitled APPARATUS AND METHOD FOR TRACE STREAM IDENTIFICATION OF A PIPELINE FLATTENER PRIMARY CODE FLUSH FOLLOWING INITIATION OF AN INTERRUPT SERVICE ROUTINE; invented by Gary L. Swoboda, Bryan Thome and Manisha Agarwala, filed on even date herewith, and assigned to the assignee of the present application; U.S. patent application (Attorney Docket No. TI-34666), entitled APPARATUS AND METHOD FOR TRACE STREAM IDENTIFICATION OF A PIPELINE FLATTENER SECONDARY CODE FLUSH FOLLOWING A RETURN TO PRIMARY CODE EXECUTION, invented by Gary L. Swoboda, Bryan Thome and Manisha Agarwala filed on even date herewith, and assigned to the assignee of the present application; U.S. patent application (Docket No. TI-34667), entitled APPARATUS AND METHOD IDENTIFICATION OF A PRIMARY CODE START SYNC POINT FOLLOWING A RETURN TO PRIMARY CODE EXECUTION, invented by Gary L. Swoboda, Bryan Thome and Manisha Agarwala, filed on even date herewith, and assigned to the assignee of the present application; U.S. patent application (Attorney Docket No. TI-34668), entitled APPARATUS AND METHOD FOR IDENTIFICATION OF A NEW SECONDARY CODE START POINT FOLLOWING A RETURN FROM A SECONDARY CODE EXECUTION, invented by Gary L. Swoboda, Bryan Thome and Manisha Agarwala, filed on even date herewith, and assigned to the assignee of the present application; U.S. patent application (Attorney Docket No. TI-34669), entitled APPARATUS AND METHOD FOR TRACE STREAM IDENTIFICATION OF A PAUSE POINT IN A CODE EXECTION SEQUENCE, invented by Gary L. Swoboda, Bryan Thome and Manisha Agarwala, filed on even date herewith, and assigned to the assignee of the present application; U.S. patent application (Attorney Docket No. TI-34670), entitled APPARATUS AND METHOD FOR COMPRESSION OF A TIMING TRACE STREAM, invented by Gary L. Swoboda and Bryan Thome, filed on even date herewith, and assigned to the assignee of the present application; U.S. patent application (Attorney Docket No. TI-34671), entitled APPARATUS AND METHOD FOR TRACE STREAM IDENTIFCATION OF MULTIPLE TARGET PROCESSOR EVENTS, invented by Gary L. Swoboda and Bryan Thome, filed on even date herewith, and assigned to the assignee of the present application are related applications.

### BACKGROUND OF THE INVENTION

1. Field of the Invention

This invention relates generally to the testing of digital signal processing units and, more particularly, to the signals that are transmitted from a target processor to a host processing to permit analysis of the target processor operation. Certain events in the target processor must be communicated to the host processing unit along with contextual information. In this manner, the test and debug data can be analyzed and problems in the program or operation of the target processor identified.

2. Description of the Related Art

As microprocessors and digital signal processors have become increasingly complex, advanced techniques have been developed to test these devices. Dedicated apparatus is available to implement the advanced techniques. Referring to FIG. 1A, a general configuration for the test and debug of a target processor 12 is shown. The test and debug procedures operate under control of a host processing unit 10. The host processing unit 10 applies control signals to the emulation unit 11 and receives (test) data signals from the emulation unit 11 by cable connector 14. The emulation unit 11 applies control signals to and receives (test) signals from the target processing unit 12 by connector cable 15. The emulation unit 11 can be thought of as an interface unit between the host processing unit 10 and the target processor 12. The emulation unit 11 processes the control signals from the host processor unit 10 and applies these signals to the target processor 12 in such a manner that the target processor will respond with the appropriate test signals. The test signals from the target processor 12 can be a variety types. Two of the most popular test signal types are the JTAG (Joint Test Action Group) signals and trace signals. The JTAG protocol provides a standardized test procedure in wide use in which the status of selected components is determined in response to control signals from the host processing unit. Trace signals are signals from a multiplicity of selected locations in the target processor 12 during defined period of operation. While the width of the bus 15 interfacing to the host processing unit 10 generally has a standardized dimension, the bus between the emulation unit 11 and the target processor 12 can be increased to accommodate an increasing amount of data needed to verify the operation of the target processing unit 12. Part of the interface function between the host processing unit 10 and the target processor 12 is to store the test signals until the signals can be transmitted to the host processing unit 10.

Referring to FIG. 1B, the operation of the trigger generation unit 19 is shown. The trigger generation unit 19 provides the main component by which the operation/state of the target processor can be altered. At least one event signal is applied to the trigger generation unit 19. Based on the identity of the event signal(s) applied to the trigger generation unit 19, a resultant trigger signal is selected. Certain events and combination of events, referred to as an event front, generate a selected trigger signal that results in certain activity in the target processor, e.g., a debug halt. Combinations of different events generating trigger signals are referred to as jobs. Multiple jobs can have the same trigger signal or combination of trigger signals. In the test and debug of the target processor, the trigger signals can provide impetus for changing state in the target processor or for performing a specified activity. The event front defines the reason for the generation of trigger signal. This information is important in understanding the operation of the target processor because, as pointed out above, several combinations of events can result in the generation of a trigger signal. In order to analyze the operation of the target processing unit, the portion of the code resulting in the trigger signal must be identified. However, the events in the host processor leading to the generation of event signals can be complicated. Specifically, the characteristics of an instruction at a program counter address can determine whether a trigger signal should be generated. A trigger signal can be an indication of when an address is within a range of addresses, outside of a range of addresses, some combination of address characteristics, and/or the address is aligned with a reference address. In this instance, the address can be the program address of an instruction or a memory address directly or indirectly referenced by a program instruction.

In the prior art, the trace streams carry test and debug data from the target processor to the host processing unit has been performed using packets. The trace packets are groups of data that are transmitted together. The packets are relatively small, e.g., 10 bits wide in the preferred implementation. The packets can be transmitted in packet groups or can be transmitted individually. The small size of the packets permits great flexibility in transmission through non-standardized interfaces and in the storage of the packets prior to the reconstruction of the operation of the target processor by the host processing unit. In addition, the small size of the packets results in much of the information being spread over a series of packets. Because of the relatively small size of the packets, the amount of control information, e.g., op codes, is severely limited. To further complicate the reconstruction of the target processor operation, the packet groups are transmitted without separation in the trace stream to maximize the use of available bandwidth.

A need has been felt for apparatus and an associated method having the feature of incorporating data in relatively small packets for transmission in a trace stream. It would be yet another feature of the apparatus and associated method to provide flexibility in transmitting data in groups of packets. It would a still another feature of the apparatus and associated method to provide packets of logic signals that include an extension portion and a payload portion. It would be still another feature of the present invention to provide, in groups of packets, a header, the header providing including fields for defining the meaning of the extension portion of the following packets. It would be a still further feature of the apparatus and associated method to provide flexibility in the number of packets used to transmit a single data field. It would be yet a further feature of the apparatus and associated method to use the extension portion of the packet as an op code for defining the logic signals in the packet.

### SUMMARY OF THE INVENTION

The aforementioned and other features are accomplished, according to the present invention, by providing the target processor with at least two trace streams. One of the trace streams is a timing trace stream. The second trace stream is the program counter trace stream. A variety of groups of packets are transmitted specifying information needed to reconstruct the operation of the target processor. In the preferred embodiment, each packet includes a (2-bit) extension portion and an (8-bit) payload portion. A first 2-bit extension defines a header packet (or packets). The (2-bit) extension portions specify packet group continues, one defining a new field packet for the packet group and the second defining field continuation packet. Number of new field packets can be defined in the packet group header. When the packet group is defined in this manner, the end of a packet group can be defined and the following packet group need not have a packet header.

Other features and advantages of present invention will be more clearly understood upon reading of the following description and the accompanying drawings and the claims.

### BRIEF DESCRIPTION OF THE DRAWINGS

FIG. 1A is a general block diagram of a system configuration for test and debug of a target processor, while FIG. 1B illustrates a chip having a plurality of target processors.

FIG. 2 is a block diagram of selected components in the target processor used the testing of the central processing unit of the target processor according to the present invention.

FIG. 3 is a block diagram of selected components of the illustrating the relationship between the components transmitting trace streams in the target processor.

FIG. 4A illustrates format by which the timing packets are assembled according to the present invention, while FIG. 4B illustrates the inclusion of a periodic sync ID packet in the timing trace stream.

FIG. 5 illustrates the parameters for sync markers in the program counter stream packets according to the present invention.

FIG. 6A illustrates the sync markers in the program counter trace stream when a periodic sync point ID is generated, while FIG. 6B illustrates the reconstruction of the target processor operation from the trace streams according to the present invention.

FIG. 7 is a block diagram illustrating the apparatus used in reconstructing the processor operation from the trace streams according to the present invention

FIG. 8 is block diagram illustrating the of the program counter sync marker generator unit according to the present invention.

FIG. 9A illustrates the portions of a packet used as a header in a packet group; FIG. 9B illustrates a header for a packet group in which the header includes two packets; and FIG. 9C is an example of a packet group illustrating the function of the extension portion of the packets.

### DESCRIPTION OF THE PREFERRED EMBODIMENT

### 1. Detailed Description of the Figures

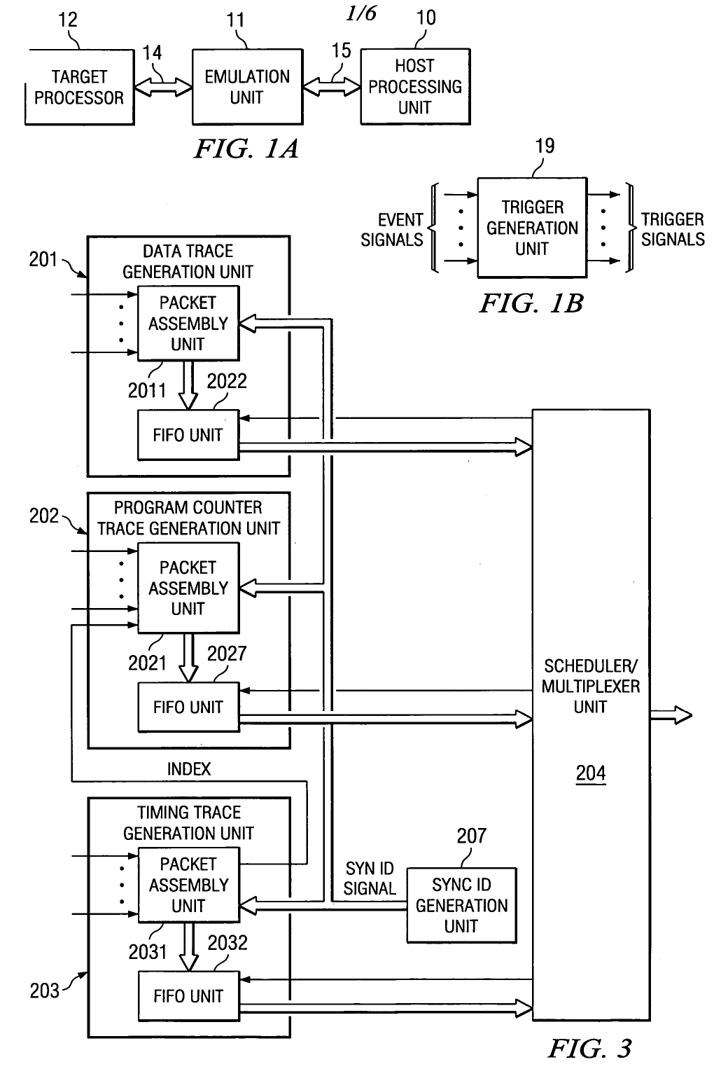

FIG. 1A and FIG. 1B have been described with respect to the related art.

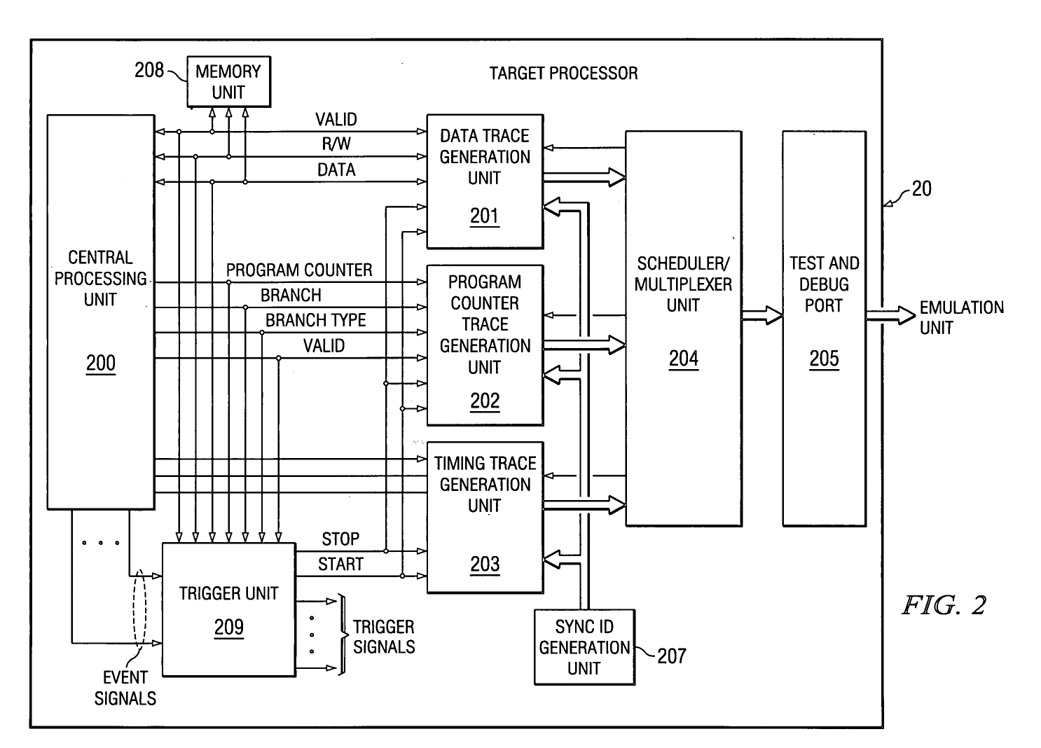

Referring to FIG. 2, a block diagram of selected components of a target processor 20, according to the present invention, is shown. The target processor includes at least one central processing unit 200 and a memory unit 208. The central processing unit 200 and the memory unit 208 are the components being tested. The trace system for testing the central processing unit 200 and the memory unit 202 includes three packet generating units, a data packet generation unit 201, a program counter packet generation unit 202 and a timing packet generation unit 203. The data packet generation unit 201 receives VALID signals, READ/WRITE signals and DATA signals from the central processing unit 200. After placing the signals in packets, the packets are applied to the scheduler/multiplexer unit 204 and forwarded to the test and debug port 205 for transfer to the emulation unit 11. The program counter packet generation unit 202 receives PROGRAM COUNTER signals, VALID signals, BRANCH signals, and BRANCH TYPE signals from the central processing unit 200 and, after forming these signal into packets, applies the resulting program counter packets to the scheduler/multiplexer 204 for transfer to the test and debug port 205. The timing packet generation unit 203 receives ADVANCE signals, VALID signals and CLOCK signals from the central processing unit 200 and, after forming these signal into packets, applies the resulting packets to the scheduler/multiplexer unit 204 and the scheduler/multiplexer 204 applies the packets to the test and debug port 205. Trigger unit 209 receives EVENT signals from the central processing unit 200 and signals that are applied to the data trace generation unit 201, the program counter trace generation unit 202, and the timing trace generation unit 203. The trigger unit 209 applies TRIGGER and CONTROL signals to the central processing unit 200 and applies CONTROL (i.e., STOP and START) signals to the data trace generation unit 201, the program counter generation unit 202, and the timing trace generation unit 203. The sync ID generation unit 207 applies signals to the data trace generation unit 201, the program counter trace generation unit 202 and the timing trace generation unit 203. While the test and debug apparatus components are shown as being separate from the central processing unit 201, it will be clear that an implementation these components can be integrated with the components of the central processing unit 201.

Referring to FIG. 3, the relationship between selected components in the target processor 20 is illustrated. The data trace generation unit 201 includes a packet assembly unit 2011 and a FIFO (first in/first out) storage unit 2012, the program counter trace generation unit 202 includes a packet assembly unit 2021 and a FIFO storage unit 2022, and the timing trace generation unit 203 includes a packet generation unit 2031 and a FIFO storage unit 2032. As the signals are applied to the packet generators 201, 202, and 203, the signals are assembled into packets of information. The packets in the preferred embodiment are 10 bits in width. Packets are assembled in the packet assembly units in response to input signals and transferred to the associated FIFO unit. The scheduler/multiplexer 204 generates a signal to a selected trace generation unit and the contents of the associated FIFO storage unit are transferred to the scheduler/multiplexer 204 for transfer to the emulation unit. Also illustrated in FIG. 3 is the sync ID generation unit 207. The sync ID generation unit 207 applies an SYNC ID signal to the packet assembly unit of each trace generation unit. The periodic signal, a counter signal in the preferred embodiment, is included in a current packet and transferred to the associated FIFO unit. The packet resulting from the SYNC ID signal in each trace is transferred to the emulation unit and then to the host processing unit. In the host processing unit, the same count in each trace stream indicates that the point at which the trace streams are synchronized. In addition, the packet assembly unit 2031 of the timing trace generation unit 203 applies and INDEX signal to the packet assembly unit 2021 of the program counter trace generation unit 202. The function of the INDEX signal will be described below.

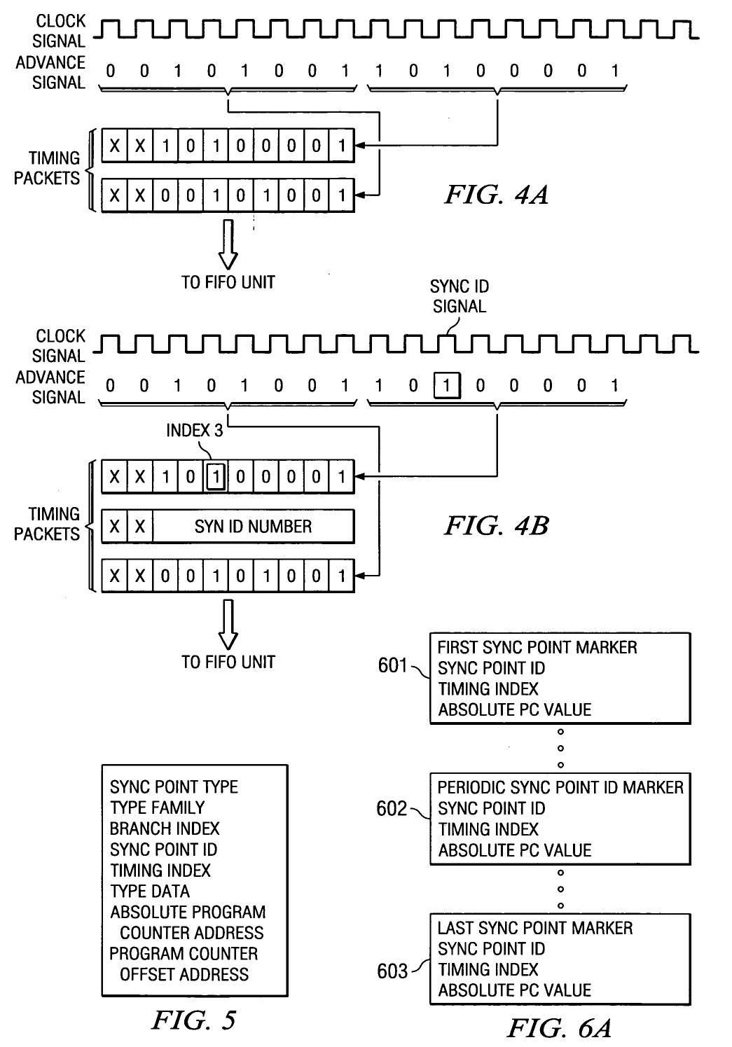

Referring to FIG. 4A, the assembly of timing packets is illustrated. The signals applied to the timing trace generation unit 203 are the CLOCK signals and the ADVANCE signals. The CLOCK signals are system clock signals to which the operation of the central processing unit 200 is synchronized. The ADVANCE signals indicate an activity such as a pipeline advance or program counter advance (( )) or a pipeline non-advance or program counter non-advance (1). An ADVANCE or NON-ADVANCE signal occurs each clock cycle. The timing packet is assembled so that the logic signal indicating ADVANCE or NON-ADVANCE is transmitted at the position of the concurrent CLOCK signal. These combined CLOCK/ADVANCE signals are divided into groups of 8 signals, assembled with two control or extension bits in the packet assembly unit 2031, and transferred to the FIFO storage unit 2032.

Referring to FIG. 4B, the trace stream generated by the timing trace generation unit 203 is illustrated. The first (in time) trace packet is generated as before. During the assembly of the second trace packet, a SYNC ID signal is generated during the third clock cycle of the packet. In response, the timing packet assembly unit 2031 assembles a packet in response to the SYNC ID signal that includes the sync ID number. The next timing packet is only partially assembled at the time of the SYNC ID signal. In fact, the SYNC ID signal occurs during the third clock cycle of the formation of this timing packet. The timing packet assembly unit 2031 generates a TIMING INDEX 3 signal (for the third packet clock cycle at which the SYNC ID signal occurs) and transmits this TIMING INDEX 3 signal to the program counter packet assembly unit 2031.

Referring to FIG. 5, the parameters of a sync marker in the program counter trace stream, according to the present invention is shown. The program counter stream sync markers each have a plurality of packets associated therewith. The packets of each sync marker can transmit a plurality of parameters. A SYNC POINT TYPE parameter defines the event described by the contents of the accompanying packets. A program counter TYPE FAMILY parameter provides a context for the SYNC POINT TYPE parameter and is described by the first two most significant bits of a second header packet. A BRANCH INDEX parameter in all but the final SYNC POINT points to a bit within the next relative branch packet following the SYNC POINT. When the program counter trace stream is disabled, this index points a bit in the previous relative branch packet when the BRANCH INDEX parameter is not a logic “0”. In this situation, the branch register will not be complete and will be considered as flushed. When the BRANCH INDEX is a logic “0”, this value point to the least significant value of branch register and is the oldest branch in the packet. A SYNC ID parameter matches the SYNC POINT with the corresponding TIMING and/or DATA SYNC POINT which are tagged with the same SYNC ID parameter. A TIMING INDEX parameter is applied relative to a corresponding TIMING SYNC POINT. For all but LAST POINT SYNC events, the first timing packet after the TIMING PACKET contains timing bits during which the SYNC POINT occurred. When the timing stream is disabled, the TIMING INDEX points to a bit in the timing packet just previous to the TIMING SYNC POINT packet when the TIMING INDEX value is nor zero. In this situation, the timing packet is considered as flushed. A TYPE DATA parameter is defined by each SYNC TYPE. An ABSOLUTE PC VALUE is the program counter address at which the program counter trace stream and the timing information are aligned. An OFFSET COUNT parameter is the program counter offset counter at which the program counter and the timing information are aligned.

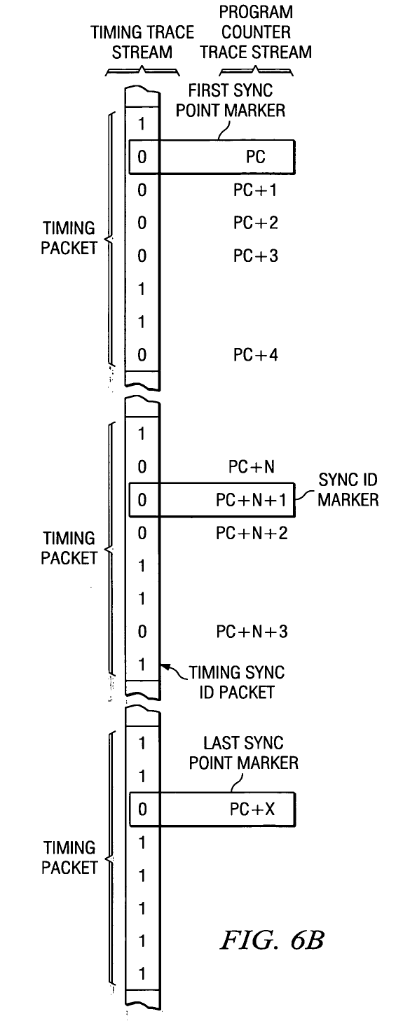

Referring to FIG. 6A, a program counter trace stream for a hypothetical program execution is illustrated. In this program example, the execution proceeds without interruption from external events. The program counter trace stream will consist of a first sync point marker 601, a plurality of periodic sync point ID markers 602, and last sync point marker 603 designating the end of the test procedure. The principal parameters of each of the packets are a periodic sync point type, a sync point ID, a timing index, and an absolute PC value. The first and last sync points identify the beginning and the end of the trace stream. The sync ID parameter is the value from the value from the most recent sync point ID generator unit. In the preferred embodiment, this value in a 3-bit logic sequence. The timing index identifies the status of the clock signals in a packet, i.e., the position in the 8 position timing packet when the event producing the sync signal occurs. And the absolute address of the program counter at the time that the event causing the sync packet is provided. Based on this information, the events in the target processor can be reconstructed by the host processor.

Referring to FIG. 6B, the reconstruction of the program execution from the timing and program counter trace streams is illustrated. The timing trace stream consists of packets of 8 logic “0”s and logic “1”s. The logic “0”s indicate that either the program counter or the pipeline is advanced, while the logic “1”s indicate the either the program counter or the pipeline is stalled during that clock cycle. Because each program counter trace packet has an absolute address parameter, a sync ID, and the timing index in addition to the packet identifying parameter, the program counter addresses can be identified with a particular clock cycle. Similarly, the periodic sync points can be specifically identified with a clock cycle in the timing trace stream. In this illustration, the timing trace stream and the sync ID generating unit are in operation when the program counter trace stream is initiated. The periodic sync point is illustrative of the plurality of periodic sync points that would typically be available between the first and the last trace point, the periodic sync points permitting the synchronization of the three trace streams for a processing unit.

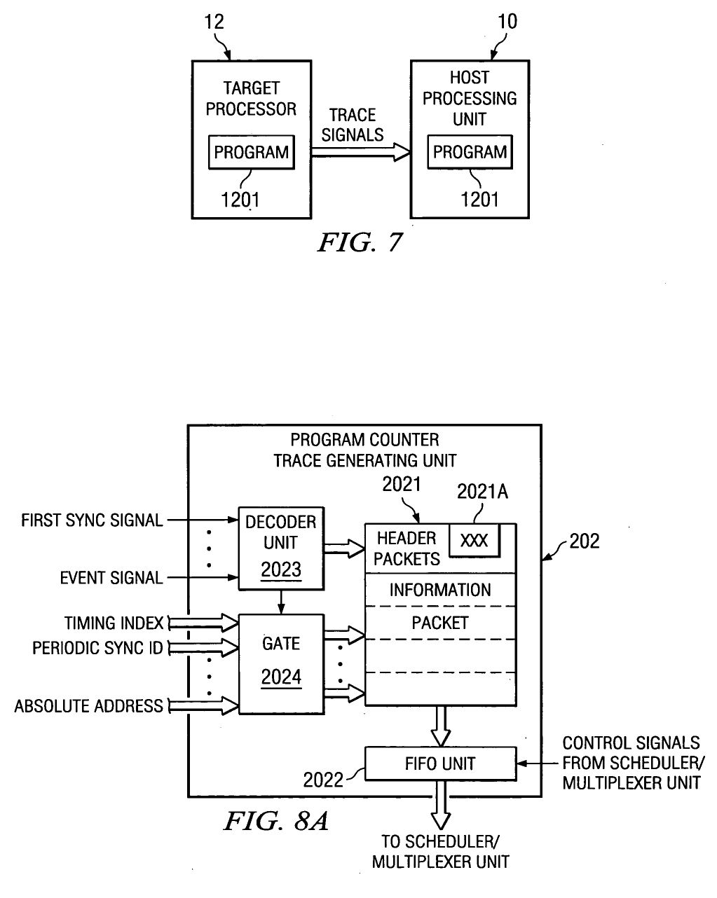

Referring to FIG. 7, the general technique for reconstruction of the trace streams is illustrated. The trace streams originate in the target processor 12 as the target processor 12 is executing a program 1201. The trace signals are applied to the host processing unit 10. The host processing unit 10 also includes the same program 1201. Therefore, in the illustrative example of FIG. 6 wherein the program execution proceeds without interruptions or changes, only the first and the final absolute addresses of the program counter are needed. Using the advance/non-advance signals of the timing trace stream, the host processing unit can reconstruct the program as a function of clock cycle. Therefore, without the sync ID packets, only the first and last sync markers are needed for the trace stream. This technique results in reduced information transfer. FIG. 6 includes the presence of periodic sync ID cycles, of which only one is shown. The periodic sync ID packets are important for synchronizing the plurality of trace streams, for selection of a particular portion of the program to analyze, and for restarting a program execution analysis for a situation wherein at least a portion of the data in the trace data stream is lost. The host processor can discard the (incomplete) trace data information between two sync ID packets and proceed with the analysis of the program outside of the sync timing packets defining the lost data.

Referring to FIG. 8, the major components of the program counter packet generation unit 202 is shown. The program counter packet generation unit 202 includes a decoder unit 2023, storage unit 2021, a FIFO unit 2022, and a gate unit 2024. PERIODIC SYNC ID signals, TIMING INDEX signals, and ABSOLUTE ADDRESS signals are applied to gate unit 2024. When the PERIODIC SYNC ID signals are incremented, the decoder unit 2023, in response to the PERIODIC SYNC ID signal, stores a periodic sync ID header signal group in a predetermined location 2021A of the header portion of the storage unit 2021. The PERIODIC SYNC signal causes the gate 2024 to transmit the PERIODIC SYNC ID signals, the TIMING INDEX signals and the ABSOLUTE ADDRESS signals. These transmitted signals are stored in the storage unit 2021 in information packet locations assigned to these parameters. When all of the portions of the periodic sync marker have been assembled in the storage unit 2021, then the component packets of the periodic sync marker are transferred to the FIFO unit 2022 for eventual transmission to the scheduler/multiplexer unit. Similarly, when an EVENT signal is generated and applied to the decoder unit 2023, the event header identifying signal group is stored in position 2021A in the header portion of the storage unit 2021. The DEBUG HALT signal applied to decoder unit 2023 results in a control signal being applied to the gate 2024. As a result of the control signal, the SYNC ID signals, the TIMING INDEX signals, and the ABSOLUTE ADDRESS signals are stored in the appropriate locations in storage unit 2021. When the event signal sync marker has been assembled, i.e., in packets, the event sync marker is transferred to the FIFO unit 2022. The program counter trace stream, along with the periodic sync markers permits the synchronization of the plurality of trace streams. This synchronization is particularly important if there is an interruption in one or more trace streams. The trace streams can be resynchronized without restarting the process.

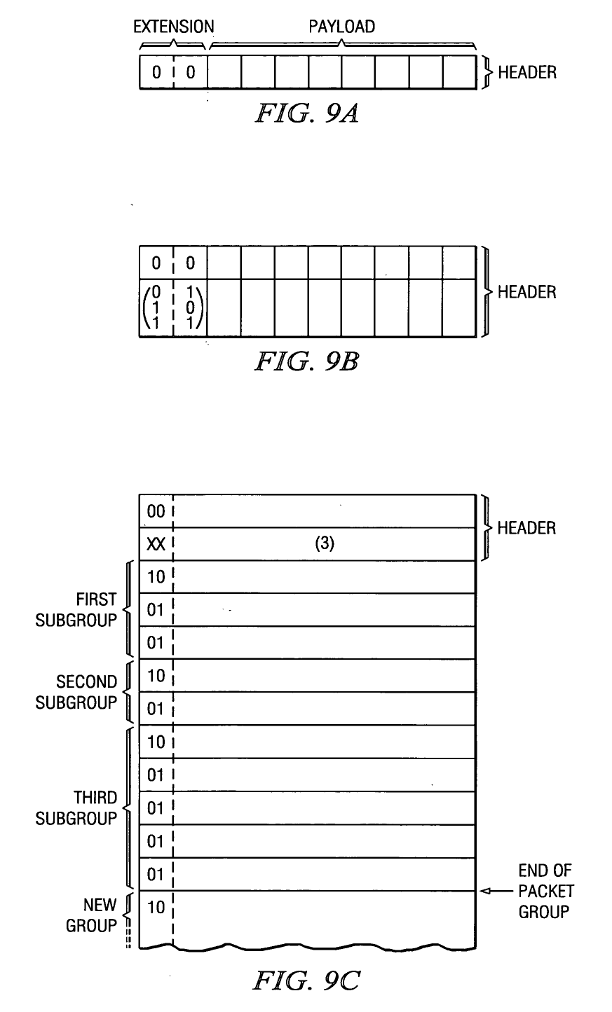

The foregoing discussion has been direct to providing examples of the manner in which the sub-groups, such as sync markers, are used in test and debug procedures. The signals transmitted over the trace streams are organized in packets as shown in FIG. 9A. In the preferred embodiment, the trace packet has 10 bit positions including a 2-bit extension portion and an 8-bit payload portion. In the preferred embodiment, (0 0) in the extension portion indicates a header. Because of relatively limited amount of signal capacity, 8 bits may not be sufficient to accommodate the header information. Therefore, in the preferred embodiment, two sequential packets are used to transmit the header information. Because this protocol is strictly enforced, the second extension can have any of the three remaining combinations of logic signals, i.e., (0 1), (10), (1 1). These three combinations can be used to designate additional information concerning the header of the packet group. This protocol is illustrated in FIG. 9B. In FIG. 9C, a full packet group, according to the present invention, is shown. Note that in the (two packet) header, one field has a logic group that is a representation of 3. In the protocol of the present invention, the three designates the number of packet sub-groups in the packet group. The first packet of the packet sub-group is designated by an extension having (1 0) stored therein. The following packets that include the extension (0 1) are continuation packets of the sub-packet. The presence of the next extension (1 0) designates the first packet of the next sub-group of packets. Once again, this sub-packet is continued by the following packets having the (0 1) extension. The next (1 0) in the extension indicates the beginning to the third and final sub-group. Again, the sub-group is continued by each packet having the (0 1) extension. When an extension following the third sub-group identified by an extension that is different from the (0 1) continuation extension, the packet group has ended and a new packet group is begun.

Referring once again to FIG. 9C, when the protocol is rigidly enforced, a group of packet groups related to a preselected event can be the new packet group, but without a header. In this implementation, the header is superfluous. In the preferred embodiment, sub-groups related to a branch procedure are issued without a header, the header being implied.

2. Operation of the Preferred Embodiment

The present invention is directed toward minimizing the amount of data transferred from target processor to the host processing unit while providing flexibility in formatting of the packet groups. The flexibility to expand or contract depending on the circumstances is particularly important. In the preferred embodiment, the trace data streams are comprised of packets 10 bits wide. Of the 10 bits, 2 bits are referred to as an extension and the remaining 8-bits are referred to as a payload. By adhering to a strict protocol, the bits of the extension can be used to convey different types of information, used as an op code, and can be used to designate the end of a group of packets. When the protocol is strictly followed, a group of packet groups can be generated in which a header is implied, rather than transmitted.

The sync marker trace steams illustrated above relate to an idealized operation of the target processor in order to emphasize the features of the present invention. Numerous other processor events (e.g. branch events) will typically be entered in the storage unit and included in the program counter trace stream.

In the foregoing discussion, the sync markers can have additional information embedded therein depending on the implementation of the apparatus generating and interpreting the trace streams. This information will be related to the parameters shown in FIG. 5. It will also be clear that a data trace stream, as shown in FIG. 2 will typically be present. The periodic sync IDs as well as the timing indexes will also be included in the data trace stream. In addition, the program counter absolute address parameter can be replaced by the program counter off-set register in certain situations.

One or more events in the target processor can be used to specify the generation of an event signal. Signals representing these events are applied to the trigger unit. The trigger unit includes the decision making capability to determine when an EVENT signal that should communicated to the host processing unit be generated. The EVENT signal and associated control signals not only result in the generation of the event sync marker, cause the target processor to transition to the appropriate state.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

What is claimed is:

1. A packet group for use in a trace stream, the packet group comprising:
at least one header packet; and
at least one packet subgroup, each packet having an extension portion and a payload portion, the number of packet subgroups determined by a field in the header packet, wherein the first packet in each packet subgroup includes a first extension portion, the packets following the first packet in subgroup that are a continuation of the first subgroup packet having a second extension.

2. The packet group as recited in claim 1 wherein, when in the sequence of packets of the last subgroup of patents, the next sequential packet does not have the second extension, the packet group has ended.

3. The packet group as recited in claim 2 wherein the next sequential packet begins a new packet group.

4. The packet group as recited in claim 3 wherein for selected packet groups, a header is implied for new packet groups.

5. The packet group as recited in claim 1 wherein, when the header is defined to have more than one packet, the extension portions of the packets following the first packet can be used to convey information.

6. A processor test and debug system, the system comprising:
a host processing; and
a target processor, the target processor transmitting trace streams to the host processing unit, the trace streams permitting the host processing unit to reconstruct the operation of target processing unit, at least one trace stream being comprised of a sequence of packet groups, each packet group including:
at least one header packet; and
at least one packet subgroup, each packet having an extension portion and a payload portion, the number of packet subgroups determined by a field in the header packet, wherein the first packet in each packet subgroup includes a first extension portion, the packets following the first packet in subgroup that are a continuation of the first subgroup packet having a second extension.

7. The packet group as recited in claim 6 wherein, when in the sequence of packets of the last subgroup of patents, the next sequential packet does not have the second extension, the packet group has ended.

8. The packet group as recited in claim 7 wherein the next sequential packet begins a new packet group.

9. The method for transferring information from a target processor to a host processing unit in trace streams, the method comprising:
dividing the information into packet groups;
formatting each packet group to include at least one header packet; and
formatting the packet group to include at least one packet subgroup, each packet subgroup having an extension portion and a payload portion, the number of packet subgroups determined by a field in the header packet, wherein the first packet in each packet subgroup includes a first extension portion, the packets following the first packet in subgroup that are a continuation of the first subgroup packet having a second extension.

10. The method as recited in claim 9 wherein, when in the sequence of packets of the last subgroup of patents the next sequential packet does not have the second extension, the packet group has ended.
